(19) United States
(12) Patent Application Publication
(10) Pub. No.: US 2012/0015487 A1
(43) Pub. Date: Jan. 19, 2012

(54) THIN FILM TRANSISTOR ARRAY PANEL AND METHOD FOR MANUFACTURING THE SAME INCLUDING FORMING A TEMPERATURE DEPENDENT GATE INSULATING LAYER

(76) Inventors: Sung-Hoon YANG, Seoul (KR); Won-Suk Shin, Yongin-si (KR); Byoung-June Kim, Seongnam-si (KR)

(21) Appl. No.: 13/244,036

(22) Filed: Sep. 23, 2011

Related U.S. Application Data
(62) Division of application No. 11/444,954, filed on May 31, 2006.

(30) Foreign Application Priority Data
May 31, 2005 (KR) 10-2005-0046146

(51) Int. Cl. H01L 21/336

(52) U.S. Cl. 438/158; 257/E21.409

(57) ABSTRACT

The present invention provides a thin film transistor array panel comprising a substrate; a gate line containing Ag formed on the substrate at a low temperature to prevent agglomeration, a first gate insulating layer formed on the gate line, a second gate insulating layer formed on the first gate insulating layer, a data line perpendicularly intersecting the gate line, and a thin film transistor connected to the gate line and the data line, and a manufacturing method thereof.

### REFERENCE TO RELATED APPLICATION

This is a divisional of U.S. patent application Ser. No. 11/444,954 filed on May 31, 2006 which claims priority to Korean Patent Application No. 10-2005-0046146, filed on May 31, 2005 in the Korean Intellectual Property Office, the disclosures of which are incorporated herein by reference in their entireties.

### BACKGROUND OF THE INVENTION

1. Field of the Invention

The present invention relates to a thin film transistor (TFT) array panel and a manufacturing method for the same.

2. Description of the Related Art

Liquid crystal displays (LCDs) are one of the most widely used flat panel displays. An LCD includes a liquid crystal (LC) layer interposed between two panels provided with field-generating electrodes. The LCD displays images by applying voltages to the field-generating electrodes to generate an electric field in the LC layer that determines the orientations of LC molecules and their polarization of incident light. A conventional LCD has two panels, each being provided with field-generating electrodes. One panel has a plurality of pixel electrodes arranged in a matrix and the other has a common electrode covering the entire surface of the panel. The LCD displays images by applying a different voltage to each pixel electrode. For this purpose, thin film transistors (TFTs) having three terminals to switch voltages applied to the pixel electrodes are connected to the pixel electrodes. Gate lines transmit signals for controlling the thin film transistors and data lines transmit voltages applied to the pixel electrodes. The thin film transistors may be formed on a thin film transistor array panel. A TFT is a switching element for transmitting image signals from the data line to the pixel electrode in response to scanning signals from the gate line. The TFT may be configured as a switching element to drive an active matrix organic light emitting display (AM-OLED) for controlling its respective light emitting elements.

Because of the trend to produce larger size display devices employing LCDs or AM-OLEDs, the lengths of the gate lines and the data lines are increasing with a concomitant increase in the resistance of the wiring. In order to solve the problems brought on by high resistance, such as signal delay, the gate lines and the data lines are required to be made of a material having a specific resistance as low as possible. The material having the lowest resistivity among the wiring materials is silver (Ag). However, silver reacts with the gas employed in subsequent processing and causes agglomeration and the formation of undesired protrusions in the wiring, degrading its reliability.

### SUMMARY OF THE INVENTION

The present invention provides a thin film transistor array panel and a manufacturing method therefor that produces gate lines containing Ag formed on substrate which alleviates or eliminates the agglomeration problem. The manufacturing method comprises forming a gate line containing Ag on a substrate, forming a gate insulating layer at a temperature lower than 280° C. on the gate line, forming a second gate insulating layer and a semiconductor layer at a higher temperature than the formation of the first gate insulating layer, forming a data line and a drain electrode on the second gate insulating layer, and forming a pixel electrode connected to the drain electrode.

The present invention further provides a thin film transistor array panel comprising a substrate, a gate line containing Ag formed on the substrate, a first gate insulating layer formed on the gate line, a second gate insulating layer formed on the first gate insulating layer, a data line perpendicularly intersecting the gate line, and a thin film transistor connected to the gate line and the data line.

The present invention further provides a manufacturing method of a thin film transistor array panel comprising forming a gate line containing Ag on a substrate, forming a first gate insulating layer on the gate line, forming a second gate insulating layer and a semiconductor layer at a higher temperature than the formation of the first gate insulating layer on the first gate insulating layer, forming a data line and a drain electrode on the second gate insulating layer and the semiconductor layer, and forming a pixel electrode connected to the drain electrode.

### BRIEF DESCRIPTION OF THE DRAWINGS

FIG. 1 is a layout view of a TFT array panel according to an embodiment of the present invention;

FIGS. 2 and 3 are sectional views of the TFT array panel shown in FIG. 1 taken along the line II-II and the line III-III;

FIGS. 4, 7, 10, and 13 are layout views sequentially illustrating the intermediate steps of a method of manufacturing a TFT array panel according to an embodiment of the present invention;

FIGS. 5 and 6 are sectional views of the TFT array panel shown in FIG. 4 taken along the line V-V and the line VI-VI;

FIGS. 8 and 9 are sectional views of the TFT array panel shown in FIG. 7 taken along the line VIII-VIII and the line IX-IX;

FIGS. 11 and 12 are sectional views of the TFT array panel shown in FIG. 10 taken along the line XI-XI and the line XII-XII;

FIGS. 14 and 15 are sectional views of the TFT array panel shown in FIG. 13 taken along the line XIV-XIV and the line XV-XV;

FIG. 16 is a layout view of a TFT array panel according to an embodiment of the present invention;

FIGS. 17 and 18 are sectional views of the TFT array panel shown in FIG. 16 taken along the line XVII-XVII and the line XVIII-XVIII;

FIGS. 19, 22, 25, and 28 are layout views sequentially illustrating the intermediate steps of a method of manufacturing a TFT array panel according to an embodiment of the present invention;

FIGS. 20 and 21 are sectional views of the TFT array panel shown in FIG. 19 taken along the line XX-XX and the line XXI-XXI;

FIGS. 23 and 24 are sectional views of the TFT array panel shown in FIG. 22 taken along the line XXIII-XXIII and the line XIV-XIV;

FIGS. 26 and 27 are sectional views of the TFT array panel shown in FIG. 25 taken along the line XXVI-XXVI and the line XXVII-XXVII;

FIGS. 29 and 30 are sectional views of the TFT array panel shown in FIG. 28 taken along the line XXIX-XXIX and the line XXX-XXX;

FIG. 31A is a photograph of a gate line and a storage electrode line wherein Ag agglomeration has occurred when a gate insulating layer is formed according to an existing method;

FIG. 31B is a photograph of a gate line and a storage electrode line wherein Ag agglomeration has not occurred when a gate insulating layer is formed according to an embodiment of the present invention;

FIG. 32A is a graph showing a characteristic of a TFT when a gate insulating layer is formed according to an existing method; and

FIG. 32B is a graph showing a characteristic of a TFT when a gate insulating layer is formed according to an embodiment of the present invention.

### DETAILED DESCRIPTION OF THE PREFERRED EMBODIMENTS

Preferred embodiments of the present invention will be described more fully hereinafter with reference to the accompanying drawings, in which preferred embodiments of the invention are shown. The present invention may, however, be embodied in different forms and should not be construed as being limited to the embodiments set forth herein. Rather, these embodiments are provided so that this disclosure will be thorough and complete, and will fully convey the scope of the invention to those skilled in the art. In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present.

### Embodiment 1

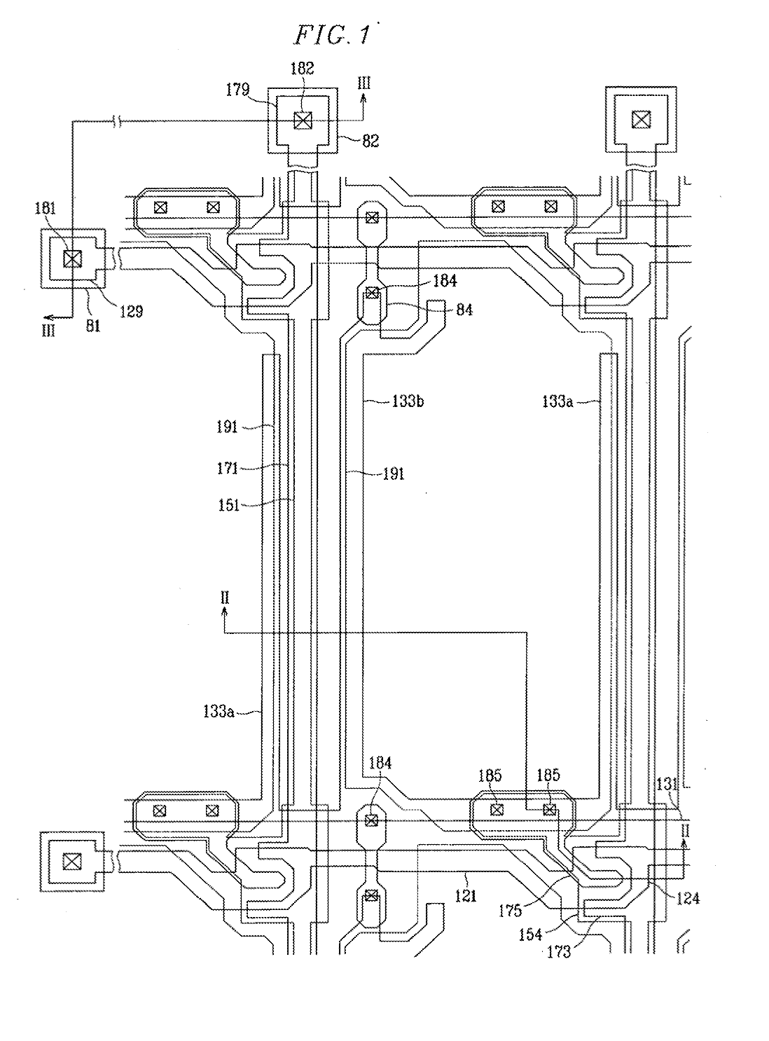

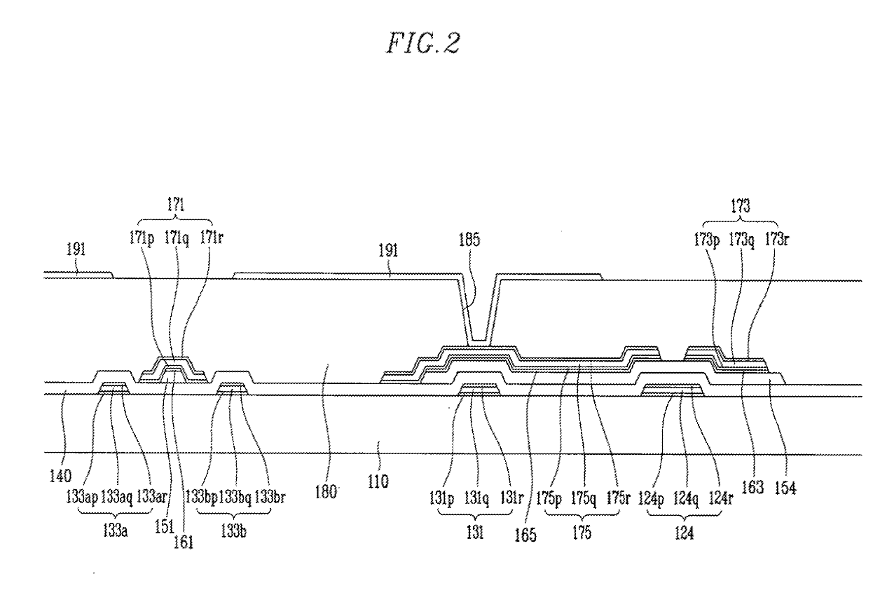

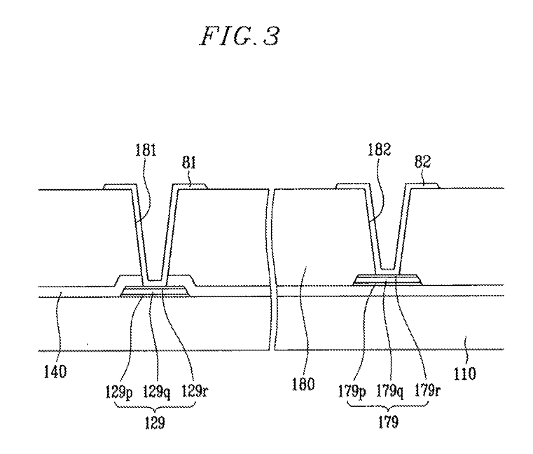

First, a TFT array panel according to an embodiment of the present invention will be described in detail with reference to FIGS. 1 to 3. FIG. 1 is a layout view of a TFT array panel according to an embodiment of the present invention, and FIGS. 2 and 3 are sectional views of the TFT array panel shown in FIG. 1 taken along the line II-II and the line III-III, respectively. A plurality of gate lines 121 and a plurality of storage electrode lines 131 are formed on an insulating substrate 110 made of a material such as transparent glass or plastic.

The gate lines 121 for transmitting gate signals extend substantially in a transverse direction. Each of the gate lines 121 includes a plurality of gate electrodes 124 that protrude downward and an end portion 129 having a large area for connection with another layer or an external driving circuit. A gate driver (not shown) for generating the gate signals may be mounted on a flexible printed circuit film (not shown) attached to the substrate 110, directly fabricated on the substrate 110, or integrated into the substrate 110. When the gate driver is integrated into the substrate 110, the gate lines 121 may be extended to be directly connected to it.

A storage electrode line 131 for receiving a prescribed voltage includes a stem line running nearly parallel with a gate line 121 and a plurality of pairs of storage electrodes 133a and 133b. Each of the storage electrode lines 131 is located between two adjacent gate lines 121, and the stem line is near the lower one of the two gate lines 121. Each of the storage electrodes 133a and 133b includes a fixed terminal connected to the stem line and a free terminal on the opposite side. The fixed terminal of the storage electrode 133b has a large area, and the free terminal of the storage electrode 133b is divided into a straight portion and a crooked portion. However, the shape and disposition of the storage electrode line 131 may be variously changed.

The gate line 121 and the storage electrode line 131 have lower layers 133ap, 133bp, 131p, 124p and 129p made of a conductive oxide such as ITO or IZO (hereinafter, referred to as “lower ITO layers”), conductive layers 133aq, 133bq, 131q, 124q and 129q containing Ag (hereinafter, referred to as “Ag-containing layers”), and upper layers 133ar, 133br, 131r, 124r and 129r made of a conductive oxide such as ITO or IZO (hereinafter, referred to as “upper ITO layers”).

The Ag-containing layers 133aq, 133bq, 131q, 124q and 129q have low resistivity to reduce the signal delay.

The lower ITO layers 133ap, 133bp, 131p, 124p and 129p and the upper ITO layers 133ar, 133br, 131r, 124r and 129r enhance adhesiveness to the substrate 110 or an upper layer respectively under and over the Ag-containing layers 133aq, 133bq, 131q, 124q and 129q.

The Ag-containing layers 133aq, 133bq, 131q, 124q and 129q are thicker than the lower ITO layers 133ap, 133 bp, 131p, 124p and 129p and the upper layers 133ar, 133br, 131r, 124r and 129r.

The lateral sides of the gate lines 121 and the storage electrode lines 131 are inclined relative to a surface of the substrate 110, and the preferable inclination angle thereof ranges from about 30 to 80 degrees.

A gate insulating layer 140 made of a material such as silicon nitride (SiNx) or silicon oxide (SiOx) is formed on the gate lines 121, the storage electrode lines 131 and the substrate 110. A plurality of semiconductor stripes 151 made of a material such as hydrogenated amorphous silicon (abbreviated to “a-Si”) or polysilicon are formed on the gate insulating layer 140. Each semiconductor stripe 151 extends substantially in the longitudinal direction and has a plurality of projections 154 branched out toward the gate electrodes 124. The width of each semiconductor stripe 151 becomes large near the gate lines 121 and the storage electrode lines 131 to cover large areas of the gate lines 121 and the storage electrode lines 131.

A plurality of ohmic contact stripes 161 and islands 165 are formed on the semiconductor stripes 151. The ohmic contacts 161 and 165 may be made of a material such as n+hydrogenated a-Si heavily doped with an n-type impurity such as phosphorus (P) or silicide. Each ohmic contact stripe 161 has a plurality of projections 163, and the projections 163 and the ohmic contact islands 165 are located in pairs on the projections 154 of the semiconductor stripes 151. The lateral sides of the semiconductor stripes 151 and the ohmic contacts 161 and 165 are also inclined relative to a surface of the substrate 110, and the inclination angle thereof ranges from about 30 to 80 degrees.

A plurality of data lines 171 and a plurality of drain electrodes 175 are formed on the ohmic contacts 161 and 165 atop the gate insulating layer 140. The data lines 171 for transmitting data voltages extend substantially in the longitudinal direction and intersect the gate lines 121. Each data line 171 also intersects the storage electrode lines 131 and is located between the adjacent storage electrodes 133a and 133b. Each data line 171 includes a plurality of source electrodes 173 branched out toward the gate electrodes 124 and an end portion 179 having a large area for connection with another layer or an external driving circuit. A data driver (not shown) for generating the data signals may be mounted on a flexible printed circuit film (not shown) attached to the substrate 110, directly fabricated on the substrate 110, or integrated into the substrate 110. When the data driver is integrated into the substrate 110, the data lines 121 may be extended to be directly connected to it.

Each drain electrode 175 is separated from the data line 171 and opposes the source electrode 173 with respect to a gate electrode 124. Each drain electrode 175 has an end portion having a large area and the other end portion being stick-shaped. The end portion having a large area overlaps the storage electrode line 131, and the stick-shaped end portion is partially surrounded by the source electrode 173 that is curved in the shape of a U.

A gate electrode 124, a source electrode 173, and a drain electrode 175, along with a projection 154 of a semiconductor stripe 151 comprise a TFT having a channel in the projection 154 disposed between the source electrode 173 and the drain electrode 175. The data line 171 and the drain electrode 175 have lower layers 171p, 173p, 175p, and 179p made of a conductive oxide such as ITO (hereinafter, referred to as “lower ITO layers”), conductive layers 171q, 173q, 175q, and 179q containing Ag (hereinafter, referred to as “Ag-containing layers”), and upper layers 171r, 173r, 175r, and 179r made of a conductive oxide such as ITO or IZO (hereinafter, referred to as “upper ITO layers”). The Ag-containing layers 171q, 173q, 175q, and 179q have low resistivity to reduce the signal delay.

The lower ITO layers 171p, 173p, 175p, and 179p and the upper ITO layers 171r, 173r, 175r, and 179r enhance adhesiveness to a lower layer or an upper layer respectively under and over the Ag-containing layers 171q, 173q, 175q, and 179q. The Ag-containing layers 171q, 173q, 175q, and 179q are thicker than the lower ITO layers 171p, 173p, 175p, and 179p and the upper layers 171r, 173r, 175r, and 179r. The lateral sides of the data lines 171 and the drain electrode 175 are also inclined relative to a surface of the substrate 110, and the inclination angles thereof are preferably in a range of about 30 to 80 degrees.

The ohmic contacts 161 and 165 are interposed only between the underlying semiconductor stripes 151 and the overlying data lines 171 and drain electrodes 175 thereon, and reduce the contact resistance therebetween. Most of the semiconductor stripe 151 is narrower than the data line 171, but as mentioned above, the width of the semiconductor stripe 151 broadens near a place where the semiconductor stripe 151 and the gate line 121 meet each other to make the profile of the surface smooth and prevent disconnection of the data line 171. The semiconductor stripe 151 is partially exposed at the place between the source electrode 173 and the drain electrode 175 and at other places not covered with the data line 171 and the drain electrode 175.

A passivation layer 180 is formed on the data line 171, the drain electrode 175, and the exposed portion of the projection 154 of the semiconductor stripe 151. The passivation layer 180 is made of a material such as an inorganic insulator such as silicon nitride or silicon oxide, an organic insulator, or a low dielectric insulator. The organic insulator and the low dielectric insulator have dielectric constants that are preferably lower than 4.0, and examples of the low dielectric insulators are a-Si:C:O and a-Si:O:F formed by plasma enhanced chemical vapor deposition (PECVD). The passivation layer 180 may be made of an organic insulator having photosensitivity, and the surface thereof may be flat. However, the passivation layer 180 may have a double-layered structure including a lower inorganic layer and an upper organic layer so as to protect the exposed portion of the projections 154 of the semiconductor stripes 151 as well as to make use of the substantial insulating property of the organic layer.

The passivation layer 180 has a plurality of contact holes 182 and 185 exposing the end portions 179 of the data lines 171 and portions of the drain electrodes 175, respectively. The passivation layer 180 and the gate insulating layer 140 have a plurality of contact holes 181 exposing the end portions 129 of the gate lines 121 and a plurality of contact holes 184 exposing portions of the storage electrode lines 131 near the fixed terminals of the storage electrodes 133b.

A plurality of pixel electrodes 191, a plurality of overpasses 84, and a plurality of contact assistants 81 and 82, which may be made of a transparent conductor such as ITO or IZO, or a reflective metal such as Al, Ag, or an alloy thereof, are formed on the passivation layer 180.

The pixel electrode 191 is physically and electrically connected with the drain electrode 175 through the contact hole 185, and it receives the data voltage from the drain electrode 175. The pixel electrode 191 to which the data voltage is applied generates an electric field with a common electrode (not shown) of the opposite panel (not shown) to which a common voltage is applied, so that the direction of the liquid crystal molecules in the liquid crystal layer (not shown) interposed between the two electrodes is determined. The pixel electrode 191 and the common electrode form a capacitor (hereinafter, referred to as a “liquid crystal capacitor”) to store and preserve the received voltage after the TFT is turned off.

The pixel electrode 191 overlaps the storage electrode line 131 including the storage electrodes 133a and 133b. To enhance the voltage storage ability, another capacitor is provided, which is connected with the liquid crystal capacitor in parallel and will be referred to as a “storage capacitor.” The pixel electrode 191 and the drain electrode 175 that are electrically connected with the pixel electrode 191 overlap the storage electrode line 131 to form a capacitor referred to as a storage capacitor, which enhances the voltage storage ability of the liquid crystal capacitor.

The contact assistants 81 and 82 are respectively connected to the end portion 129 of the gate line 121 and the end portion 179 of the data line 171 through the contact holes 181 and 182. The contact assistants 81 and 82 respectively supplement adhesion between the end portion 129 of the gate line 121 and exterior devices and between the end portion 179 of the data line 171 and exterior devices, and protects them.

The overpass 84 traverses the gate line 121, and is connected to the exposed portion of the storage electrode line 131 and the exposed end portion of the free terminal of the storage electrode 133b through the contact holes 184 which are disposed opposite each other with the gate line 121 located therebetween. The storage electrode lines 131 including the storage electrodes 133a and 133b, along with the overpasses 84, may be used to repair defects of the gate lines 121, the data lines 171, or the TFTs.

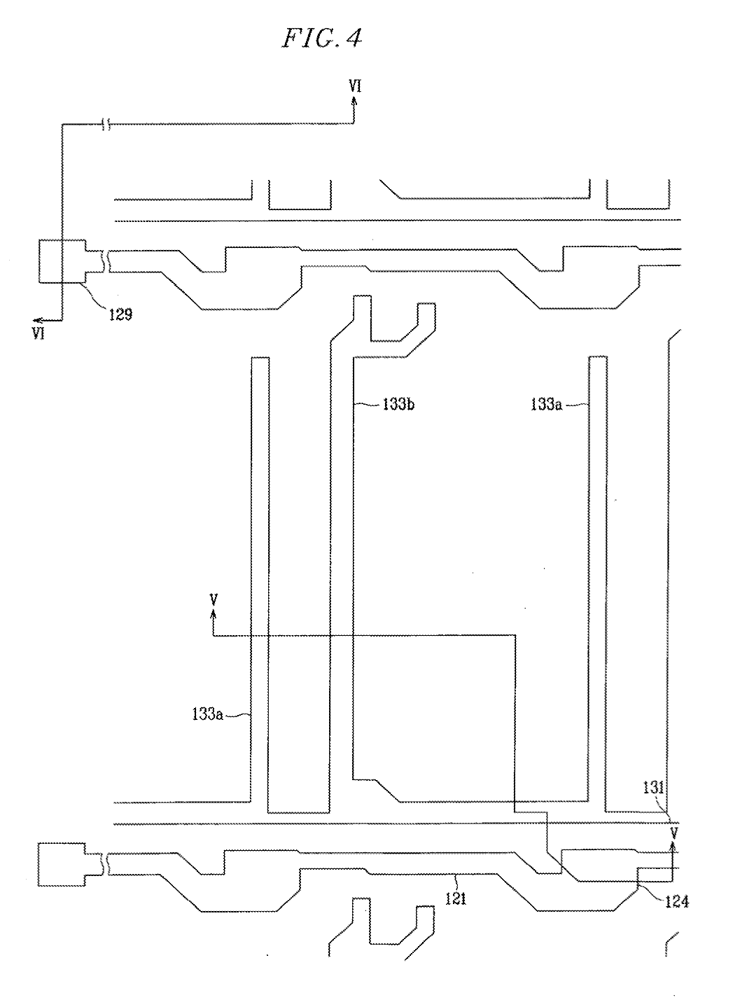

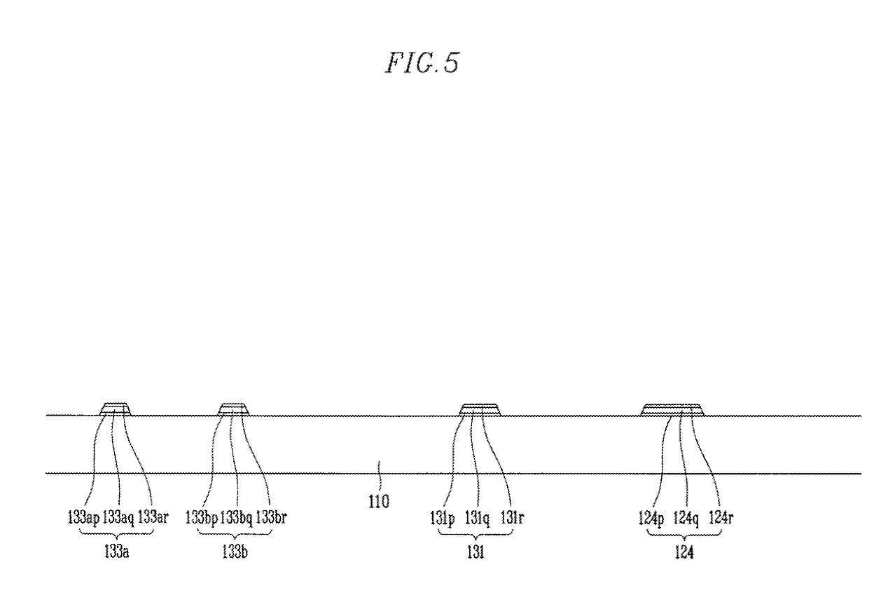

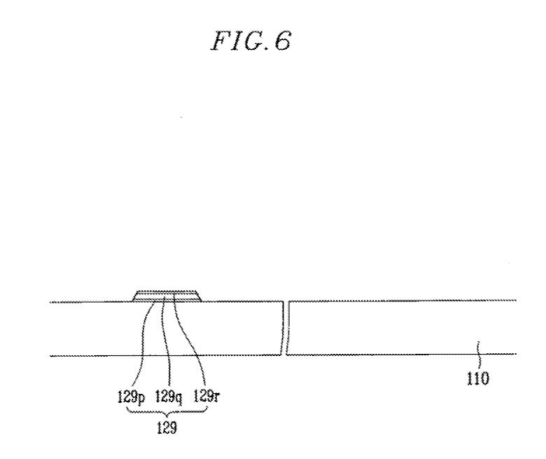

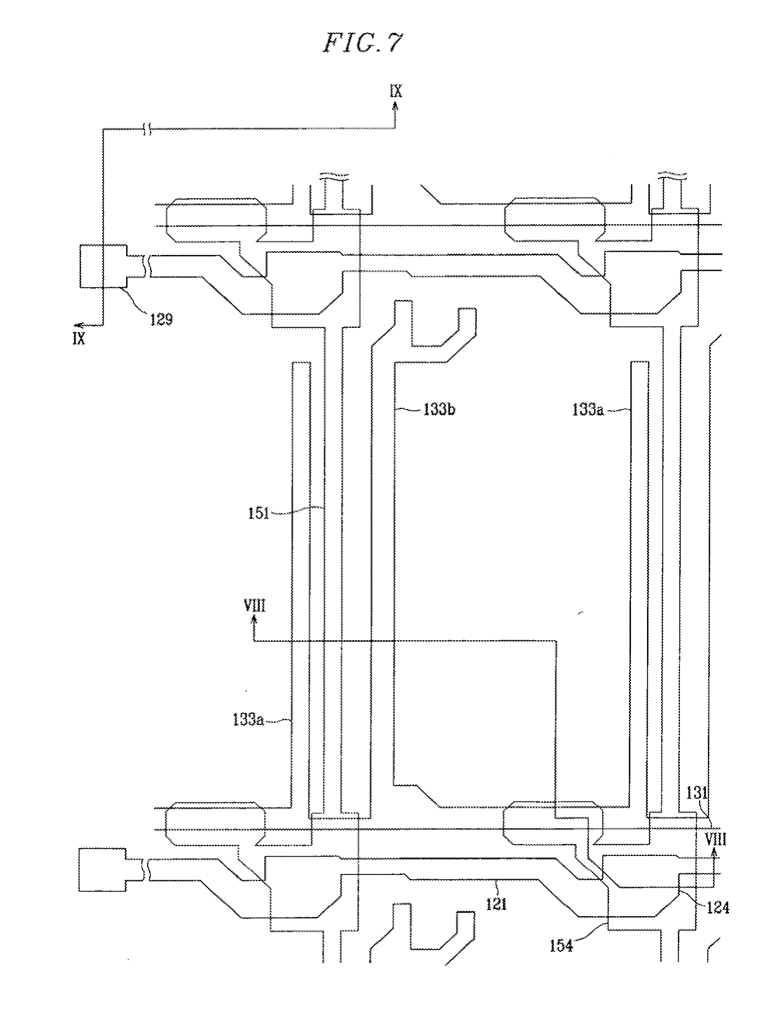

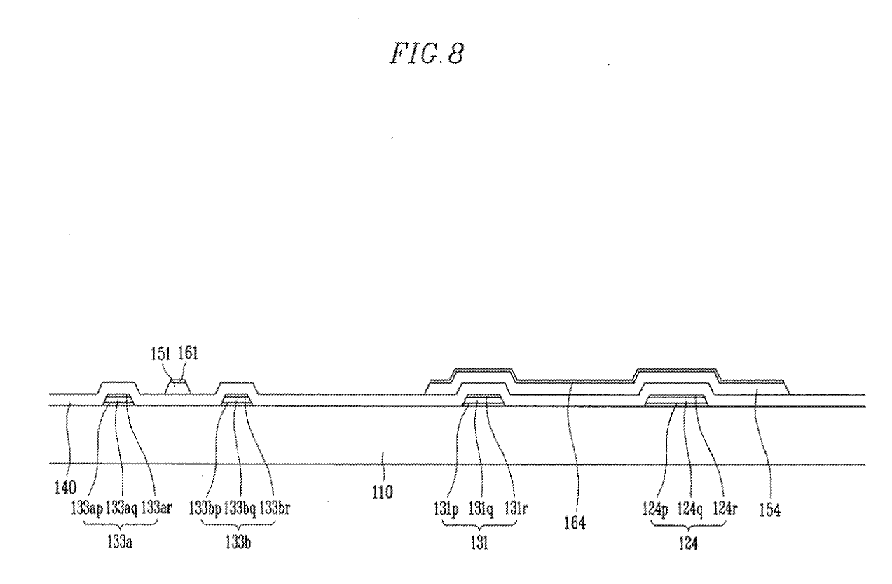

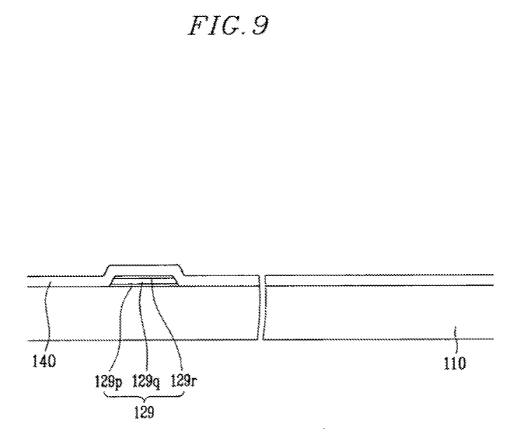

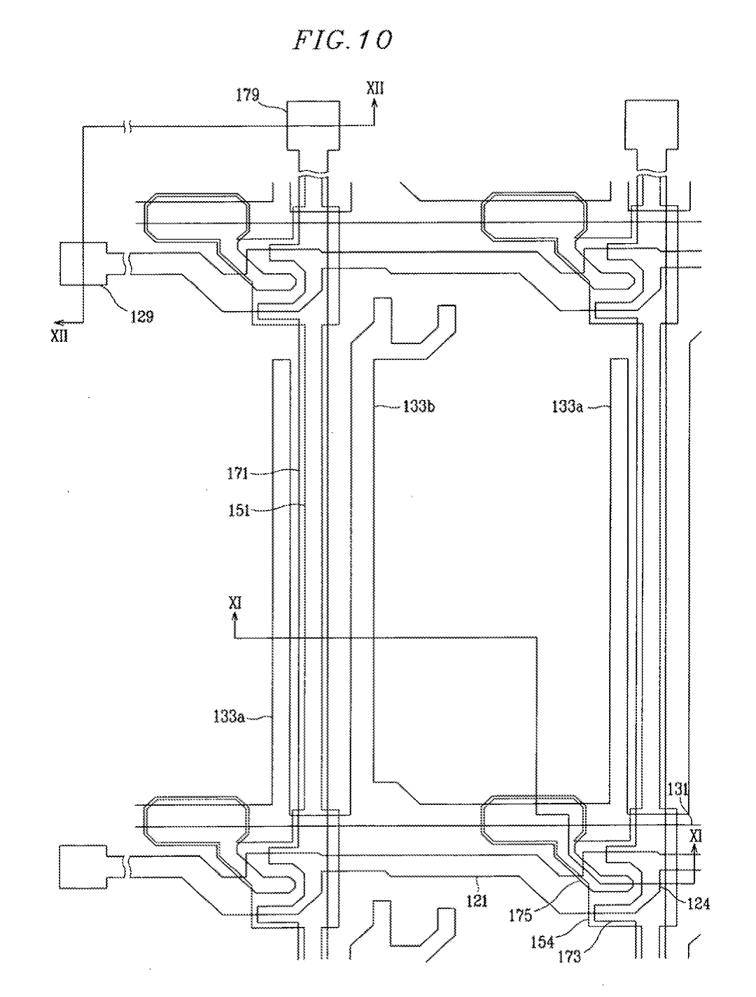

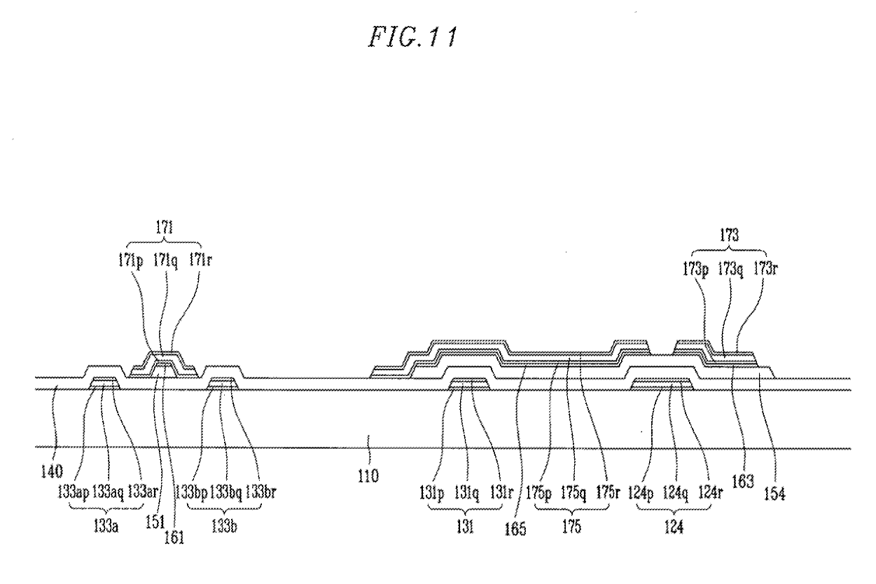

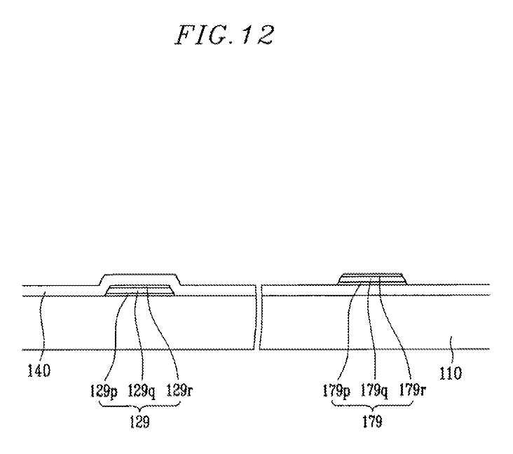

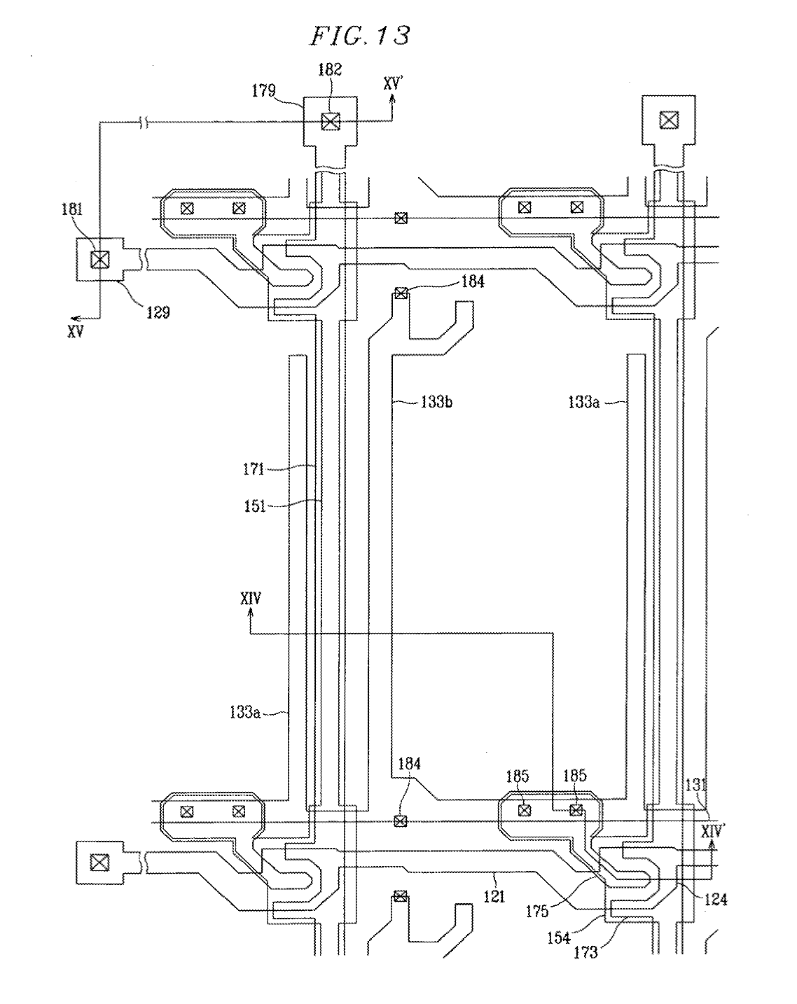

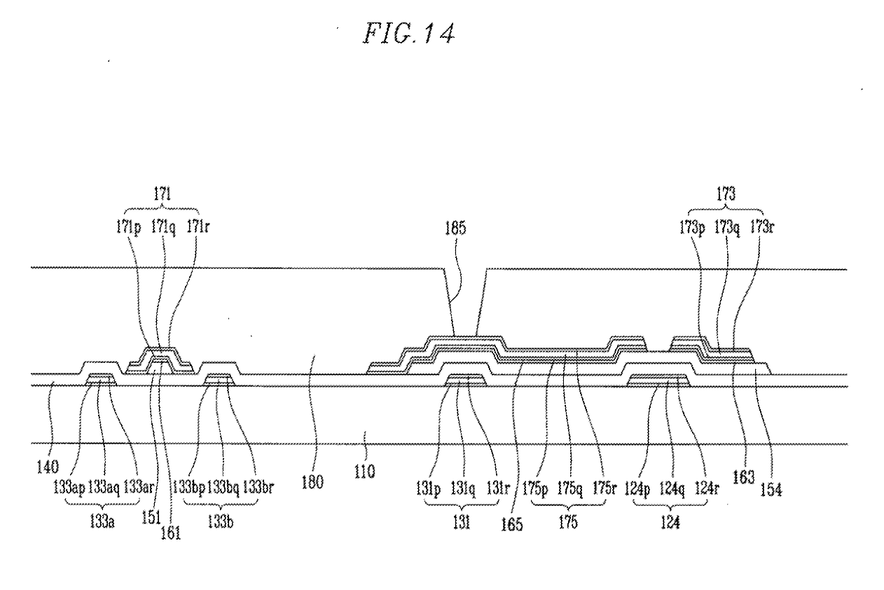

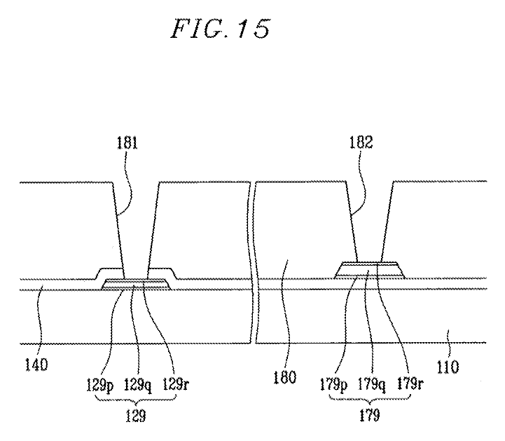

Now, a method of manufacturing the TFT array panel shown in FIGS. 1 to 3 will be described in detail with reference to FIGS. 4 to 15. FIGS. 4, 7, 10, and 13 are layout views for sequentially illustrating the intermediate steps of a method of manufacturing a TFT array panel according to an embodiment of the present invention. FIGS. 5 and 6 are sectional views of the TFT array panel shown in FIG. 4 taken along the line V-V and the line VI-VI. FIGS. 8 and 9 are sectional views of the TFT array panel shown in FIG. 7 taken along the line VIII-VIII and the line IX-IX, FIGS. 11 and 12 are sectional views of the TFT array panel shown in FIG. 10 taken along the line XI-XI and the line XII-XII, and FIGS. 14 and 15 are sectional views of the TFT array panel shown in FIG. 13 taken along the line XIV-XIV and the line XV-XV.

First, a lower ITO layer, an Ag-containing layer, and an upper ITO layer are sequentially deposited on an insulating substrate 110 made of a material such as transparent glass or plastic. ITO layer and the Ag-containing layer are formed by sputtering. At first, power is applied to the ITO target while no power is applied to the Ag target to deposit an ITO layer on the substrate 110. After the power applied to the ITO target is turned off, power is applied to the Ag target to deposit an Ag layer on the lower ITO layer. When the power applied to the Ag target is turned off, power is applied again to the ITO target to deposit an ITO layer on the Ag conductive layer.

Next, as shown in FIGS. 4 to 6, the lower ITO layer, the Ag layer, and the upper ITO layer are simultaneously wet etched to form gate lines 121 having gate electrodes 124 and end portions 129 and storage electrode lines 131 having storage electrodes 133a and 133b. Here, the etchant may be a hydrogen peroxide (H2O2) etchant or a etchant containing phosphoric acid (H2PO3), nitric acid (HNO3), acetic acid (CH3COOH), and deionized water for the remainder in an appropriate ratio thereof.

Then, a gate insulating layer 140 made of a material such as SiNx is formed on the gate line 121 and the storage electrode line 131 by plasma enhanced chemical vapor deposition (PECVD). The deposition of the gate insulating layer 140 is performed at a temperature lower than about 280° C., which is a remarkably low temperature compared to the high temperature between about 300 and 380° C. applied in an existing method. When a gate insulating layer 140 is formed at a high temperature over about 300° C., Ag contained in the gate line 121 and the storage electrode line 131 may react with a gas such as silane gas (SiH4) or ammonia gas (NH3) that is used in the formation of the gate insulating layer 140 (made of silicon nitride (SiNx)) so as to cause agglomeration. However, when a gate insulating layer 140 is formed at a low temperature according to an embodiment of the present invention, agglomeration of Ag is prevented and reliability of the gate wiring is insured. The deposition of the gate insulating layer 140 may be performed at a temperature lower than about 280° C., preferably about 180 to 280° C., and Ag agglomeration is prevented in such a range of temperature while uniform film quality is formed.

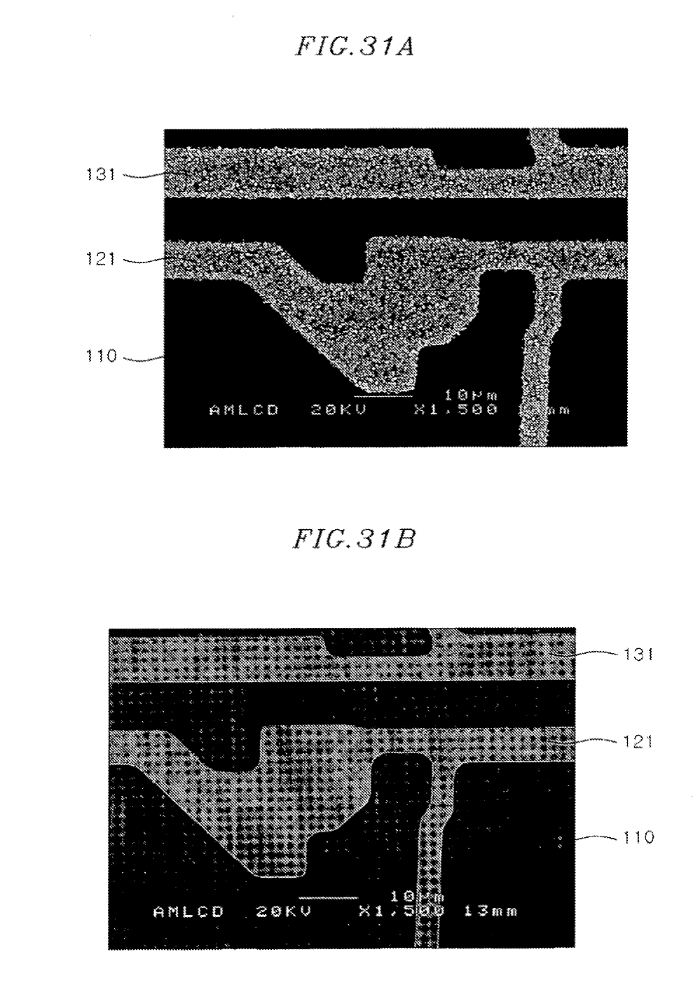

FIGS. 31A and 31B are photographs showing agglomeration in the Ag-containing layer according to a forming temperature of the gate insulating layer. FIG. 31A is a photograph of the gate line 121 and the storage electrode line 131 on the substrate 110 when the gate insulating layer is formed at a high temperature of about 320° C., showing that Ag agglomeration (white spots) occurred partially in the gate line 121 and the storage electrode line 131. FIG. 31B is a photograph of the gate line 121 and the storage electrode line 131 on the substrate 110 when the gate insulating layer is formed at a temperature of about 250° C., showing that Ag agglomeration does not occur in the gate line 121 and the storage electrode line 131.

Hydrogen gas (H₂) and/or helium gas (He) is applied along with a reacting gas such as silane gas (SiH₄), ammonia gas (NH₃), or nitrogen gas (N₂) during deposition of the gate insulating layer 140. When the gate insulating layer 140 is formed at a low temperature as in the above descriptions, the film quality may be deteriorated to influence the properties of the TFTs. Accordingly, hydrogen gas (H₂) and/or helium gas (He) is applied during deposition to prevent deterioration of the film quality and maintain the properties of the TFTs. Here, the preferable amount of hydrogen gas or helium gas applied is such that the flow ratio of H₂/SiH₄ or He/SiH₄ is maintained between 5 and 20.

Next, intrinsic a-Si and a-Si doped with an impurity are sequentially deposited on the gate insulating layer 140. Then, the a-Si doped with an impurity and the intrinsic a-Si are etched to form a gate insulating layer 140, semiconductor stripes 151 including a plurality of projections 154 made of intrinsic a-Si, and ohmic contact stripes 161 including a plurality of ohmic contact patterns 164 made of a-Si doped with the impurity. Next, a lower ITO layer, an Ag-containing layer, and an upper ITO layer are sequentially formed on the ohmic contact stripes 161 and the gate insulating layer 140. Here, the lower ITO layer, the Ag-containing layer and the upper ITO layer are formed by sputtering as with the gate line 121 and the storage electrode line 131.

Next, as shown in FIGS. 10 to 12, the lower ITO layer, the Ag-containing layer, and the upper ITO layer are simultaneously wet etched to form data lines 171 having source electrodes 173 and end portions 179, and drain electrodes 175. Next, exposed portions of the ohmic contact patterns 164 which are not covered with the source electrodes 173 and the drain electrodes 175 are removed to complete a plurality of ohmic contact stripes 161 having a plurality of projections 163 and a plurality of ohmic contact islands 165, and to expose the projections 154 of semiconductor stripes 151 below. Here, oxygen (O₂) plasma treatment may follow thereafter in order to stabilize the exposed surfaces of the projections 154.

Next, as shown in FIGS. 13 to 15, an organic material having substantial passivation properties and photosensitivity, an inorganic material such as SiNx, or a low dielectric insulating material is deposited to form a passivation layer 180 by plasma enhanced chemical vapor deposition (PECVD). The deposition of the passivation layer may be performed at a temperature lower than about 280° C., preferably between about 180 and 280° C., and in such a range of temperature Ag agglomeration in the data line 171 and the drain electrodes 175 is prevented while uniform film quality is formed.

Then, photoresist is coated on the passivation layer 180 and exposed to a light through a photo-mask, and the exposed photoresist is thereby developed to form a plurality of contact holes 181, 182, 184, and 185. Next, as shown in FIGS. 1 to 3, a transparent conductive layer such as ITO is deposited on the passivation layer 180 by sputtering and then patterned to form pixel electrodes 191, contact assistants 81 and 82, and overpasses 84.

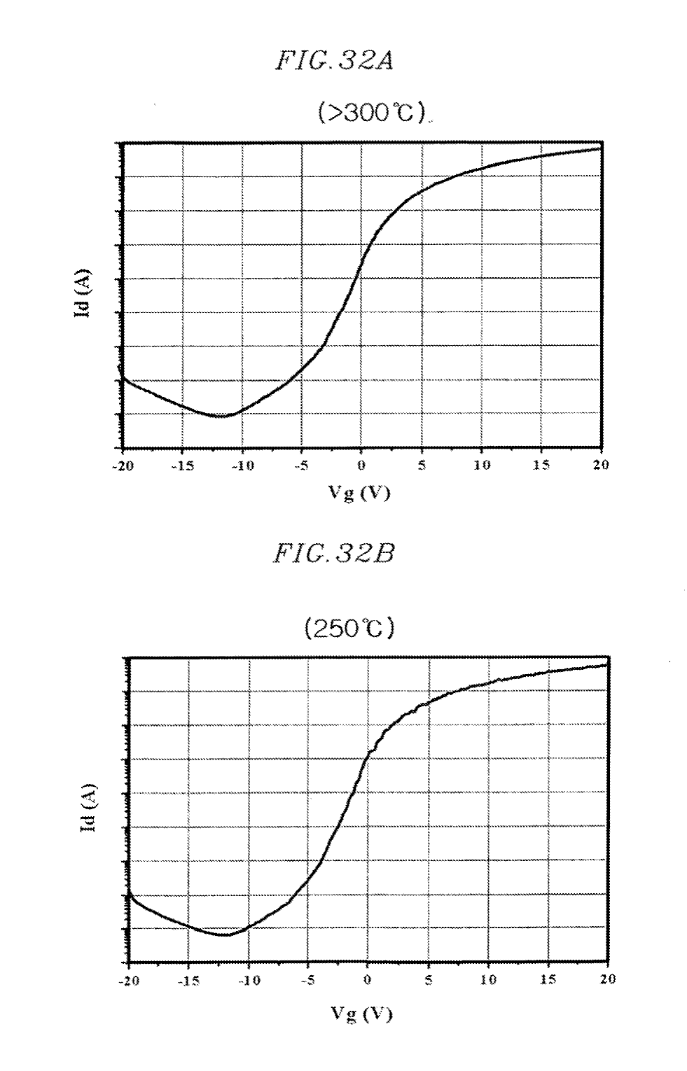

FIG. 32A is a graph showing the characteristic of current (I_{d}) according to gate voltage (V_{g}) when a gate insulating layer is formed at a temperature of about 320° C., and FIG. 32B is a graph showing the characteristic of current (I_{d}) according to gate voltage (V_{g}) when a gate insulating layer is formed at a temperature of about 250° C. while applying hydrogen gas or helium gas. As shown here, by applying hydrogen gas or helium gas together when a gate insulating layer is formed at a low temperature of about 250° C., the film quality is maintained to show similar current characteristics to those when the gate insulating layer is formed at a high temperature.

In the present embodiment, both the gate line and the data line are formed to have a lower ITO layer, an Ag-containing layer, and an upper ITO layer, but such structure may be applied to only one between them, and one of the lower ITO layer and the upper ITO layer may be omitted.

### Embodiment 2

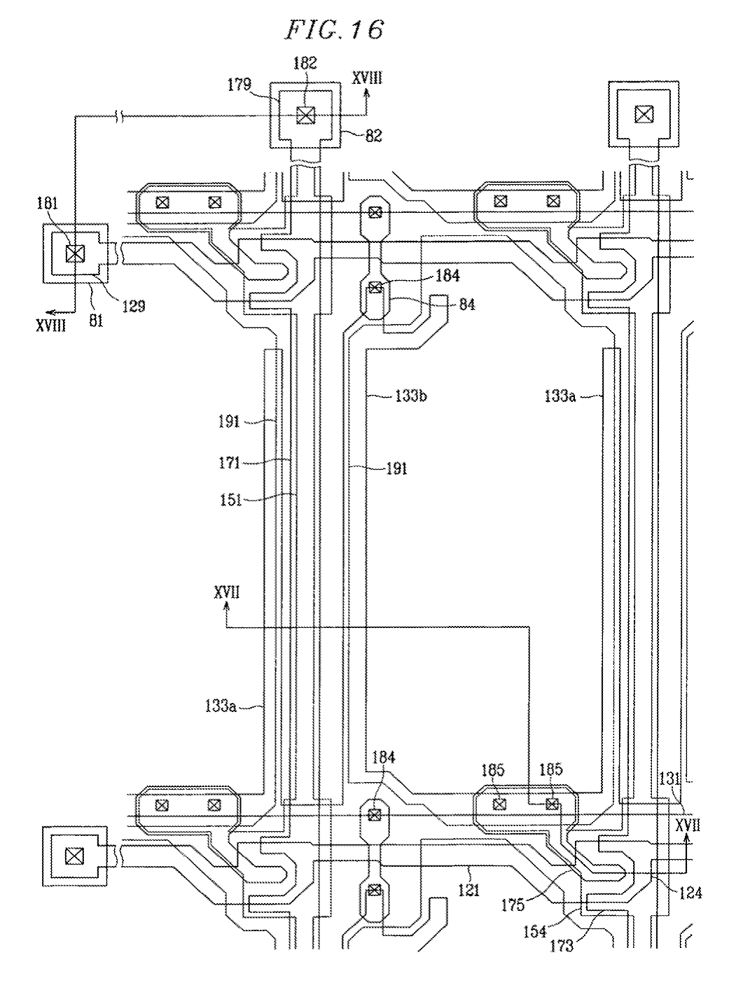

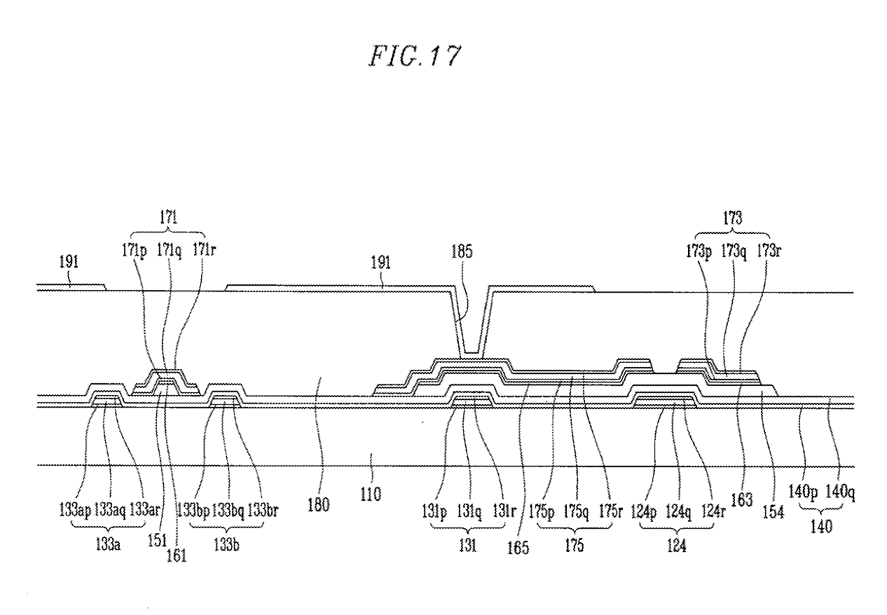

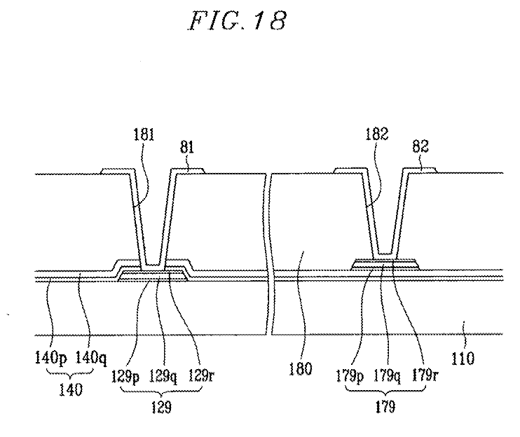

Now, a TFT array panel according to another embodiment of the present invention will be described with reference to FIGS. 16 to 18. FIG. 16 is a layout view of a TFT array panel according to an embodiment of the present invention, and FIGS. 17 and 18 are sectional views of the TFT array panel shown in FIG. 16 taken along the line XVII-XVII and the line XVIII-XVIII. The structure of the TFT array panel according to the present embodiment is substantially the same as that illustrated in FIGS. 1 to 3.

A plurality of gate lines 121 having gate electrodes 124 and end portions 129 and a plurality of storage electrode lines 131 having storage electrodes 133a and 133b are formed on a substrate 110, and a gate insulating layer 140, a plurality of semiconductor stripes 151 having projections 154, a plurality of ohmic contact stripes 161 having projections 163, and a plurality of ohmic contact islands 165 are sequentially formed thereon. A plurality of data lines 171 having source electrodes 173 and end portions 179, and a plurality of drain electrodes 175 are formed on the ohmic contacts 161 and 165, and a passivation layer 180 is formed thereon. The passivation layer 180 and the gate insulating layer 140 have a plurality of contact holes 181, 182, 184, and 185, and a plurality of pixel electrodes 191, a plurality of contact assistants 81 and 82, and a plurality of overpasses 84 are formed thereon.

However, the TFT array panel according to the present embodiment, unlike the TFT array panel shown in FIGS. 1 to 3, has a gate insulating layer 140 comprising two layers. The gate insulating layer 140 comprises a lower gate insulating layer 140p and an upper gate insulating layer 140q. Here, the lower gate insulating layer 140p is formed to have a thickness of several hundred Å, preferably 100 to 500 Å, and the upper gate insulating layer 140q is formed to have a thickness of 2000 to 4500 Å. The lower gate insulating layer 140p is a buffer layer to prevent agglomeration of Ag contained in the gate line 121 and the storage electrode line 131.

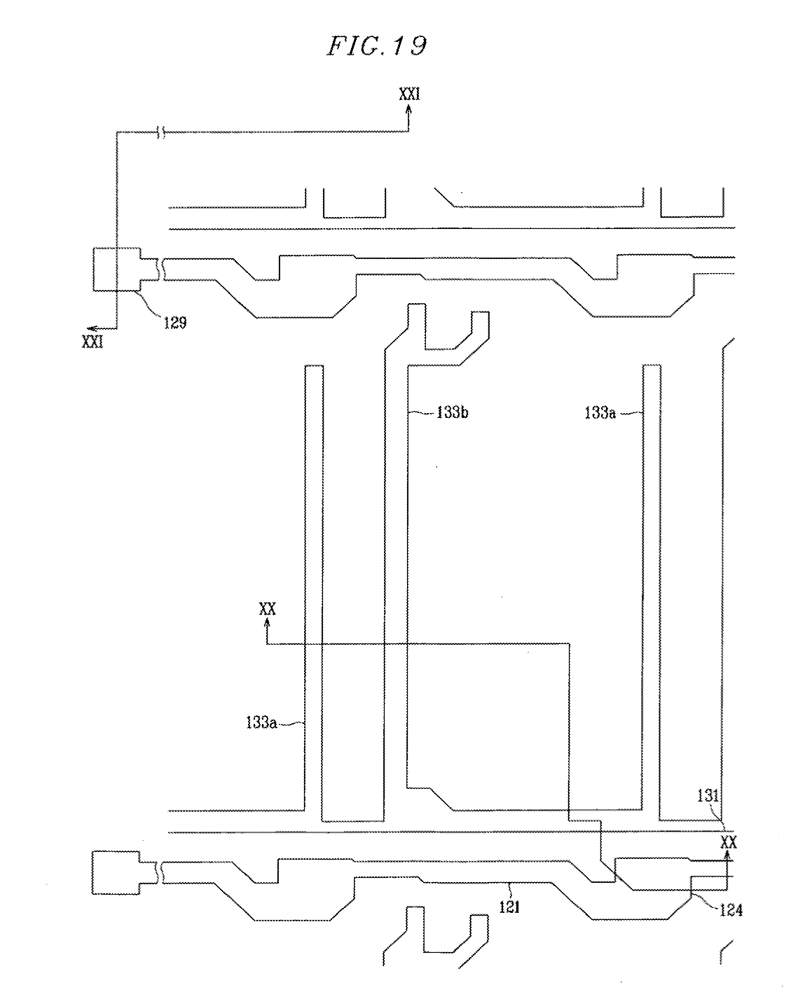

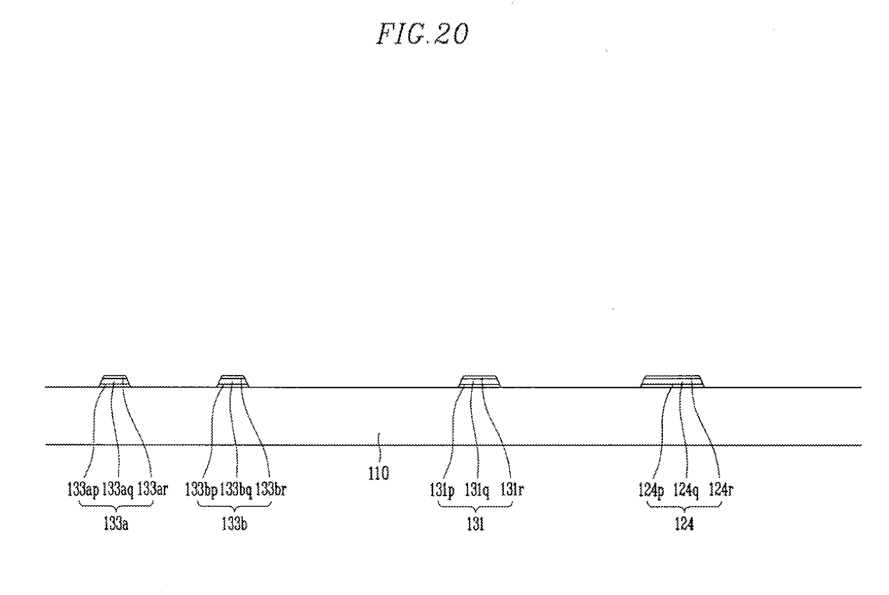

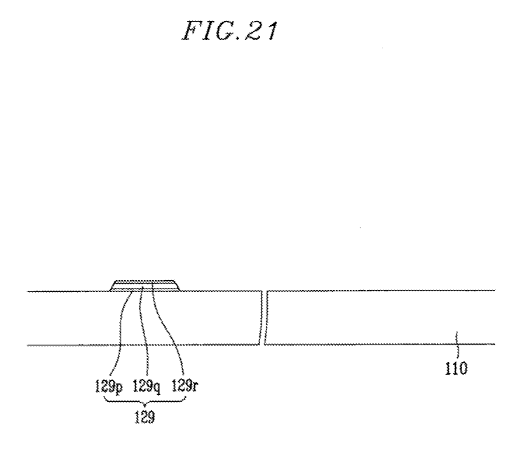

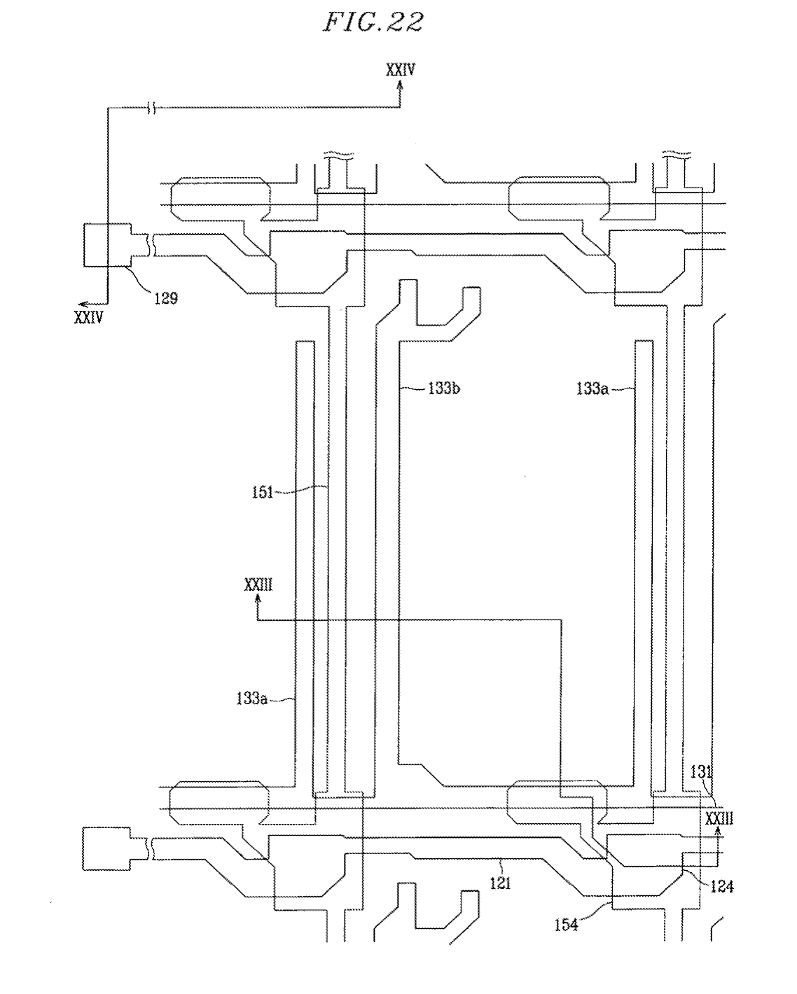

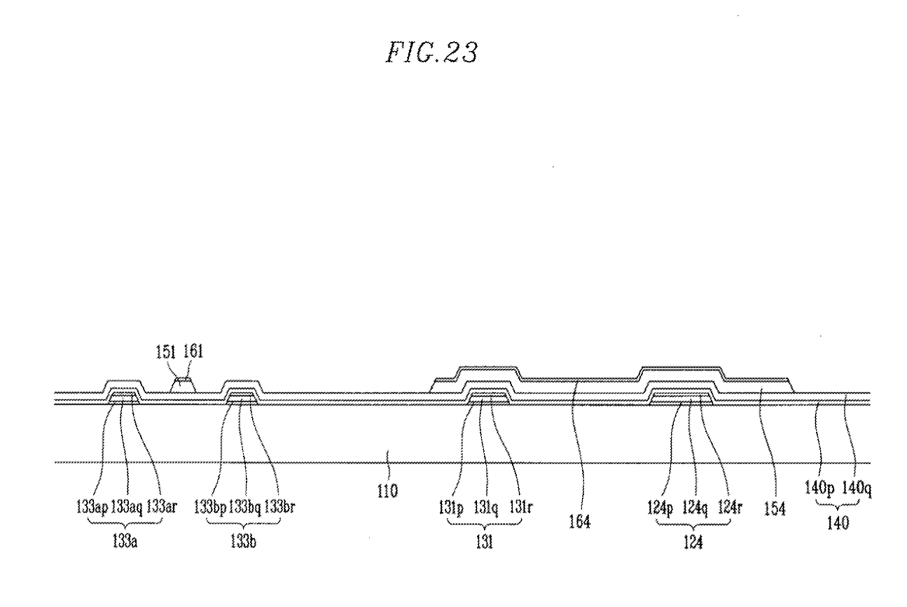

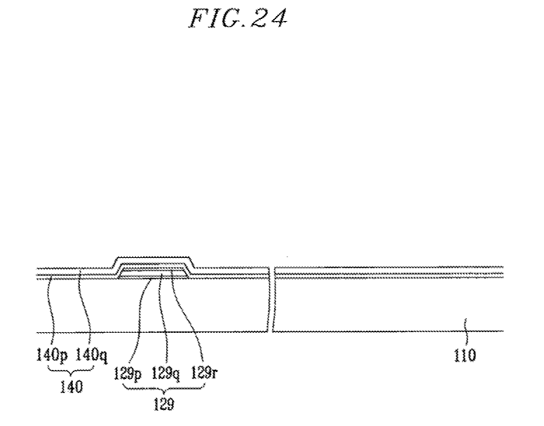

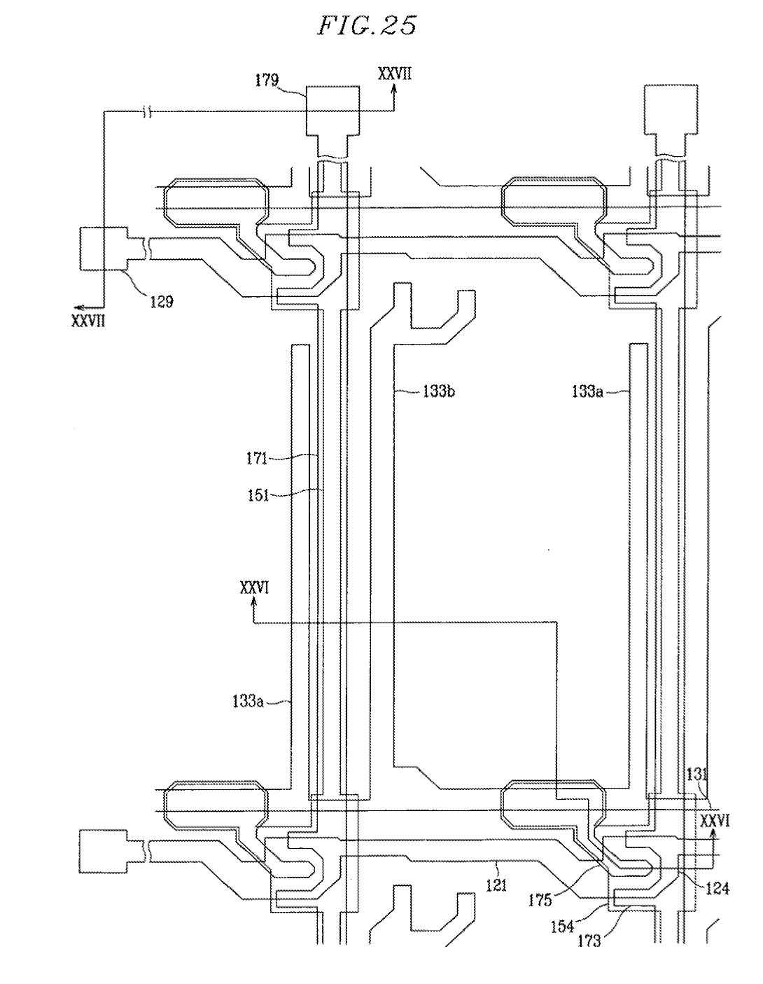

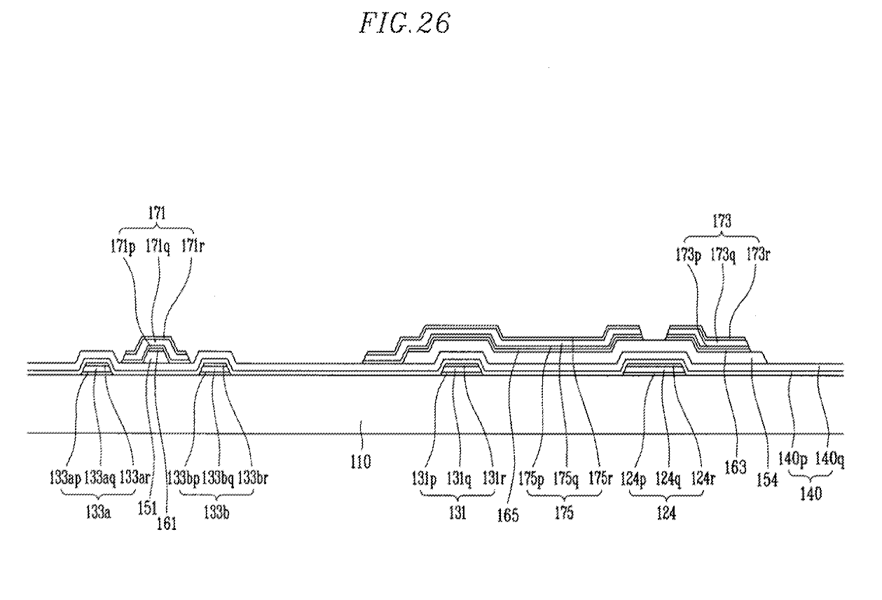

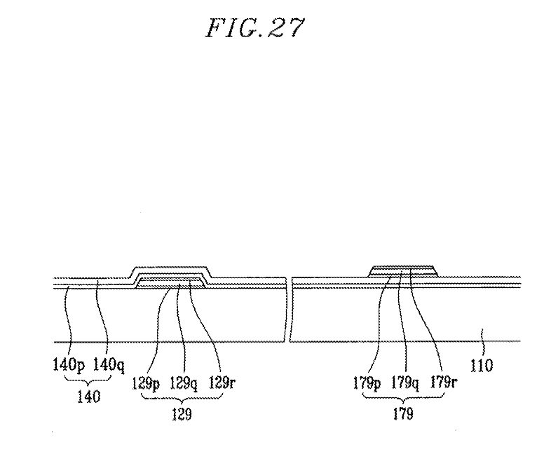

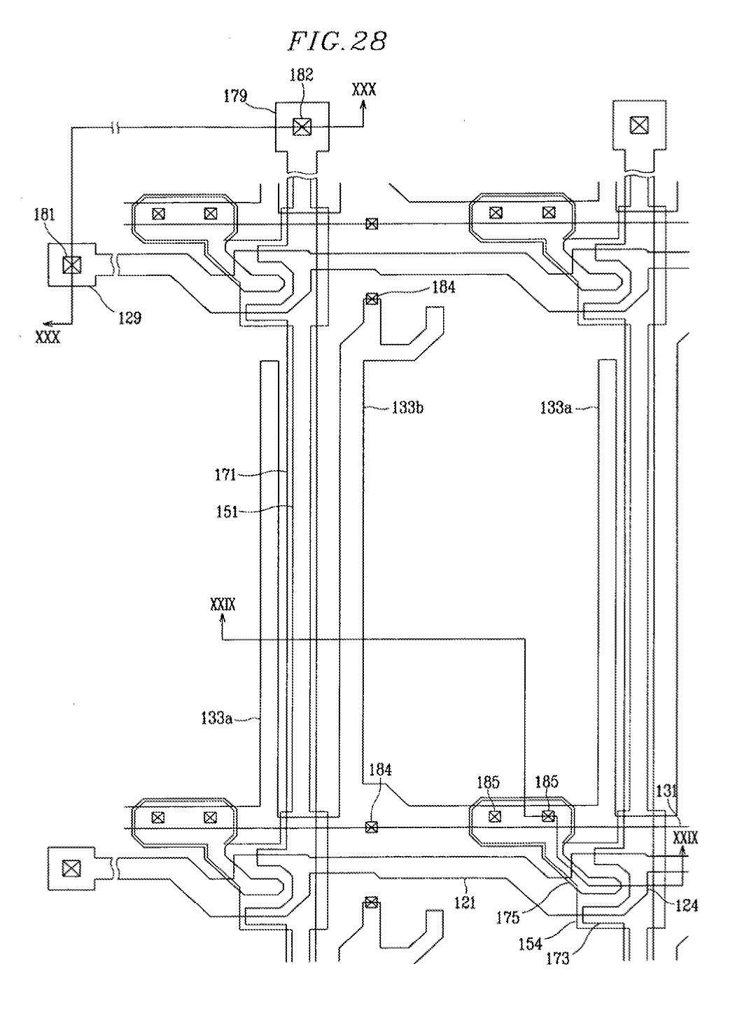

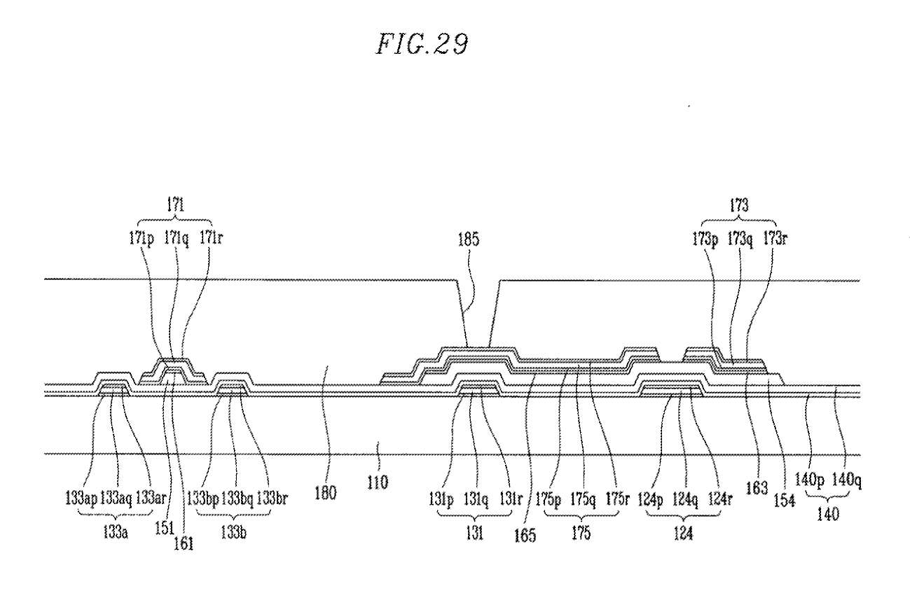

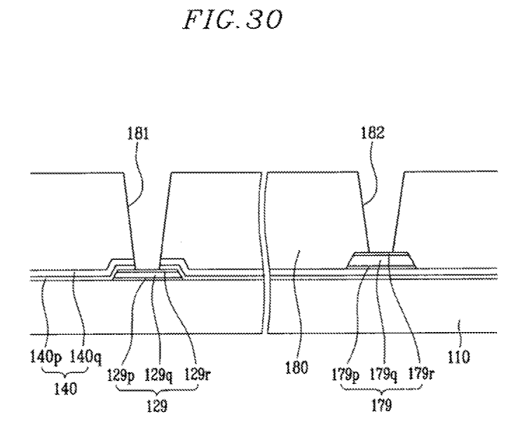

A method of manufacturing the TFT array panel according to another embodiment of the present invention will now be described with reference to FIGS. 19 to 30. FIGS. 19, 22, 25, and 28 are layout views sequentially illustrating the intermediate steps of a method of manufacturing a TFT array panel according to an embodiment of the present invention. FIGS. 20 and 21 are sectional views of the TFT array panel shown in FIG. 19 taken along the line XX-XX and the line XXI-XXI, FIGS. 23 and 24 are sectional views of the TFT array panel shown in FIG. 22 taken along the line XXIII-XXIII and the line XIV-XIV, and FIGS. 26 and 27 are sectional views of the TFT array panel shown in FIG. 25 taken along the line XXVI-XXVI and the line XXVII-XXVII. FIGS. 29 and 30 are sectional views of the TFT array panel shown in FIG. 28 taken along the line XXIX-XXIX and the line XXX-XXX.

First, as shown in FIGS. 19 to 21, a lower ITO layer, an Ag-containing layer, and an upper ITO layer are sequentially deposited on an insulating substrate 110 made of a material such as transparent glass or plastic, and then etched to form gate lines 121 having gate electrodes 124 and the end portions 129, and storage electrode lines 131 having storage electrodes 133a and 133b. A lower gate insulating layer 140p made of a material such as SiNx is then formed on the gate line 121 and the storage electrode line 131 by plasma enhanced chemical vapor deposition (PECVD). The lower gate insulating layer 140p is formed at a temperature of about 130 to 280° C., and in such a range of temperature, agglomeration of Ag contained in the gate line 121 and the storage electrode line 131 is occurred.

Next, triple layers of an upper gate insulating layer 140q, an intrinsic a-Si, and an a-Si doped with an impurity are sequentially deposited on the lower gate insulating layer 140p. Here, the deposition is performed at a high temperature of over about 300° C. Since the lower gate insulating layer 140p was formed as a buffer layer under the triple layers, agglomeration of Ag contained in the gate line 121 and the storage electrode line 131 is prevented even if the triple layers are formed at a high temperature of over about 300° C. As mentioned above, Ag agglomeration in the gate line 121 and the storage electrode line 131 is prevented by previously forming the lower gate insulating layer 140p, and on the other hand, by forming the upper gate insulating layer 140q at a high temperature, the film quality is improved and the properties of the TFTs are maintained.

Then, as shown in FIGS. 22 to 24, the a-Si doped with an impurity and the intrinsic a-Si are etched to form a gate insulating layer 140, semiconductor stripes 151 including a plurality of projections 154, and ohmic contact stripes 161 including a plurality of ohmic contact patterns 164. Next, as shown in FIGS. 25 to 27, a lower ITO layer, an Ag conductive layer, and an upper ITO layer are sequentially formed on the ohmic contact stripes 161 and the gate insulating layer 140, and then etched to form data lines 171 having source electrodes 173 and end portions 179, and drain electrodes 175.

As shown in FIGS. 28 to 30, a material such as SiNx is then deposited to form a passivation layer 180 by plasma enhanced chemical vapor deposition (PECVD), and the passivation layer 180 is photo-etched to form a plurality of contact holes 181, 182, 184, and 185. Finally, as shown in FIGS. 16 to 18, a transparent conductive layer such as ITO is deposited on the passivation layer 180 by sputtering and then patterned to form pixel electrodes 191, contact assistants 81 and 82, and overpasses 84.

As in the above descriptions, agglomeration of Ag in the gate line 121 is prevented by forming a gate insulating layer 140 at a low temperature, and on the other hand, deterioration of properties of the TFTs due to a low temperature process is prevented by applying another gas during deposition.

Although preferred embodiments of the present invention have been described in detail hereinabove, it should be clearly understood that many variations and/or modifications of the basic inventive concepts herein taught, which may appear to those skilled in the present art, will still fall within the spirit and scope of the present invention, as defined in the appended claims.

What is claimed is:

1. A manufacturing method of a thin film transistor array panel, comprising:
forming a gate line containing Ag on a substrate;
forming a first gate insulating layer on the gate line;
forming a second gate insulating layer and a semiconductor layer at a higher temperature than the formation of the first gate insulating layer on the first gate insulating layer;
forming a data line and a drain electrode on the second gate insulating layer and the semiconductor layer; and
forming a pixel electrode connected to the drain electrode.

2. The method of claim 1, wherein the formation of the first gate insulating layer is performed at a temperature of 130 to 280° C.

3. The method of claim 1, wherein the formation of the gate line comprises a step of forming a conductive layer containing a conductive oxide and a step of forming a conductive layer containing Ag.

4. The method of claim 1, wherein the formation of the data line and the drain electrode comprises deposition performed at a temperature of 180 to 280° C.

5. The method of claim 1, wherein the first gate insulating layer is thinner than the second gate insulating layer.

6. The method of claim 5, wherein a thickness of the first gate insulating layer has a range from about 100 Å to about 500 Å, and a thickness of the second gate insulating layer has a range from about 2000 Å to about 4500 Å

7. The method of claim 1, wherein the formation of the second gate insulating layer is performed at a temperature more than 300° C.
